(19) United States
(12) Patent Application Publication
(10) Pub. No.: US 2006/0183286 A1
(43) Pub. Date: Aug. 17, 2006

(54) Transistor having enlarged contact surface area and manufacturing method therefor

(75) Inventor: Seung-chul Lee, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/301,668

(22) Filed: Dec. 13, 2005

(30) Foreign Application Priority Data
Feb. 14, 2005 (KR) 10-2005-0011912

(51) Int. Cl. H01L 21/336

(52) U.S. Cl. 438/270

(57) ABSTRACT

In a transistor in which a contact surface area between a contact and a source/drain region is enlarged and a method of manufacturing the same, a lower insulating layer is formed on a substrate. Then, a semiconductor layer is formed on the lower insulating layer and selectively recessed to form a recess groove. A gate dielectric layer is formed and a gate is formed on the gate dielectric layer, wherein the gate fills the recess groove. Afterwards, a source/drain region is formed in a thick portion of the semiconductor layer, adjacent to side portions of the gate. Finally, a contact is formed to be in contact with the source/drain region, wherein a bottom end portion of the contact is partially buried in the source/drain region.

### CROSS-REFERENCE TO RELATED PATENT APPLICATION

This application claims priority to Korean Patent Application No. 10-2005-0011912, filed on Feb. 14, 2005, in the Korean Intellectual Property Office, the disclosure of which is incorporated herein in its entirety by reference.

### BACKGROUND OF THE INVENTION

1. Field of the Invention

The present invention relates to a semiconductor device, and more particularly, to a transistor of a static random access memory (SRAM) device having an enlarged contact surface area, and a manufacturing method therefor.

2. Description of the Related Art

As semiconductor devices, for example static random access memory devices. (SRAMs), become more highly integrated, transistors for such memory devices require operation at ever-higher operating speeds and with improved operational characteristics. Accordingly, a transistor having a planar structure or a fin-like structure are formed on a silicon-on-insulator (SOI) substrate for enhancing the operational characteristics, so that the channel body becomes relatively thinner. A thinner channel body operates to diminish the electric field effect for reducing an off-state current in an SRAM cell.

In this type of transistor, a source/drain is formed in the thin channel body or a thin channel silicon layer and further, a transistor gate is formed over the channel silicon layer so that a contact surface area with the source/drain is relatively decreased. However, as the contact surface area between the contact and the source/drain region becomes smaller, contact resistance becomes larger. As a result, the operational characteristics of the transistor device deteriorate, thereby affecting the overall operational characteristics of the SRAM cell employing such transistor devices.

Therefore, in order to reduce the contact resistance, it is necessary to increase the contact surface area. In one typical method in this regard a portion of a connection contact is buried in the source/drain region, to thereby enlarge the contact surface area between the connection contact and the source/drain region.

Nevertheless, structural limitations in this case limit the amount of enlargement of the contact surface area. That is, since the source/drain region is formed in the thin channel silicon layers disposed at both sides of a transistor channel, the geometry of the thin channel silicon layer makes it difficult to enlarge the contact surface area to a large degree. In other words, there is a limitation in the increase of the depth of the contact buried in the source/drain because the silicon layer is relatively thin, which makes it difficult to increase the contact surface area.

As a result, it is also difficult to reduce the contact resistance between the contact and the source/drain, whereby the transistor demonstrates relatively poor on-state current properties. That is, the increase of the contact resistance is likely to decrease the on-state current of the device.

Meanwhile, an SRAM cell generally includes a flip-flop provided with two inverters and two pass transistors connected to the flip-flop. Herein, the SRAM cell has at least six transistors. Also, the SRAM cell may incorporate therein a CMOS flip-flop. For example, a pull-up transistor and a pull-down transistor may be embodied in the CMOS flip-flop. That is, an inverter is provided with a PMOS transistor and an NMOS transistor, and two inverters constitute the CMOS flip-flop, wherein two pass transistors are connected to both sides of the flip-flop.

As described above, the SRAM cell has at lest six transistors therein so that the cell area becomes inevitably large. In addition, since the NMOS and the PMOS transistors are in the same cell, the area of the SRAM cell is relatively large. Moreover, it is necessary to form a well of a complicated structure in order to separately form the NMOS and the PMOS transistors in the same cell. Thus, such a complicated well structure results in an increase of the cell area.

### SUMMARY OF THE INVENTION

The present invention provides a transistor for an SRAM cell having a reduced contact resistance between a contact and a source/drain region of the transistor and a method of manufacturing the same. This is accomplished in a structure that effectively decreases the cell area of the SRAM cell.

According to an aspect of the present invention, there is provided a method of manufacturing a transistor for an SRAM device, including: forming a lower insulating layer on a substrate; forming a semiconductor layer on the lower insulating layer; forming a recess groove by selectively recessing the semiconductor layer; forming a gate dielectric layer on the semiconductor layer; forming a gate on the gate dielectric layer, wherein the gate fills the recess groove; forming a source/drain region in the semiconductor layer at both sides of the gate; forming an upper insulating layer covering the gate; and forming a contact which penetrates the upper insulating layer to contact the source/drain region.

In one embodiment, the method further includes before the forming of the lower insulating layer: forming a second gate dielectric layer on the substrate; forming a second gate on the second gate dielectric; and forming a second source/drain region in the substrate, adjacent to both sides of the second gate.

In another embodiment, the semiconductor layer comprises a silicon layer.

In another embodiment, the method further comprises, before forming the recess groove, carrying out a channel ion implantation into the semiconductor layer.

In another embodiment, the contact is formed such that a bottom end portion thereof is partially buried in the source/drain region of the semiconductor layer. In addition, the contact may be formed to penetrate the source/drain region of the semiconductor layer.

According to another aspect of the present invention, there is provided a transistor for an SRAM device, including: a lower insulating layer on a substrate; a semiconductor layer provided with a recess groove therein on the lower insulating layer, wherein a portion of the semiconductor layer beneath the recess groove is thinner than other portions thereof; a gate dielectric layer on the semiconductor layer; a gate on the gate dielectric layer, wherein the gate fills the recess groove; a source/drain region in the semiconductor layer, adjacent to side portions of the gate; and a contact connected to the source/drain region.

In one embodiment, the transistor further includes a second gate dielectric layer on the substrate below the lower insulating layer; a second gate on the second gate dielectric layer; and a second source/drain region in a predetermined portion of the substrate which is adjacent to side portions of the second gate.

In another embodiment, the semiconductor layer comprises a silicon layer.

In another embodiment, a bottom end portion of the contact is partially buried in the source/drain region of the semiconductor layer.

In another embodiment, the contact penetrates through the source/drain region of the semiconductor layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of an SRAM device in accordance with an embodiment of the present invention; and

FIGS. 2 through 8 are cross sectional views illustrating a transistor of the SRAM device of FIG. 1 and a method of manufacturing the same in accordance with an embodiment of the present invention,

### DETAILED DESCRIPTION OF EMBODIMENTS OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

According to an embodiment of the present invention, there is provided a transistor having a channel region with a relatively thin body so as to limit an electric field, thereby having a reduced off-state current. In addition, a source/drain region of the transistor has a relatively thick body so as to increase a contact surface area with a contact. Thus, as the contact surface area is larger, the contact resistance of the contact is effectively decreased, thereby increasing the on-state current of the transistor.

According to another embodiment of the present invention, there is provided a multi-stack transistor in which a plurality of transistors are stacked vertically. In detail, a first transistor is formed on a substrate and then an insulation layer is formed over the first transistor. Thereafter, a second transistor is formed on the insulating layer. Therefore, it is possible to embody a highly integrated semiconductor device incorporating a memory cell such as an SRAM cell having a plurality of transistors.

Furthermore, when forming the second transistor, a semiconductor layer is formed on the insulating layer and then a predetermined portion of the semiconductor layer corresponding to a channel region of the second transistor is recessed, to thereby form the channel region having a thin body. Also, by forming a recess groove in the semiconductor layer, the source/drain region of the second transistor can be formed to be relatively thicker than the channel region. In addition, since a bottom end portion of a contact is buried in the source/drain region in the thick body of the semiconductor layer, it is possible to effectively reduce the contact resistance. between the contact and the source/drain region of the second transistor.

Accordingly, with regard to the second transistor, since the channel region is formed in the thin body of the semiconductor layer, the off-state current can be reduced by means of an electric field dispersion effect. Furthermore, since the source/drain is formed in the thick body of the semiconductor layer, the contact resistance of the contact can be effectively reduced and thereby increase the on-state current.

A transistor of the present invention is amenable for use in an SRAM cell, among other types of cells or circuits.

FIG. 1 is a circuit diagram of an SRAM device in accordance with an embodiment of the present invention.

Referring to FIG. 1, the SRAM cell includes a memory terminal configured as a flip-flop circuit having two CMOS inverters and two pass transistors PS1 and PS2 connected to a bit line and a word line for reading/writing data of the memory terminal. The two CMOS inverters respectively include pull-down transistors PD1 and PD2 and pull-up transistors PU1 and PU2.

In this case, two or three transistors can be stacked vertically to thereby decrease the cell area of the SRAM. The transistors of the multi-stack structure can be formed, for example, using the following manufacturing method.

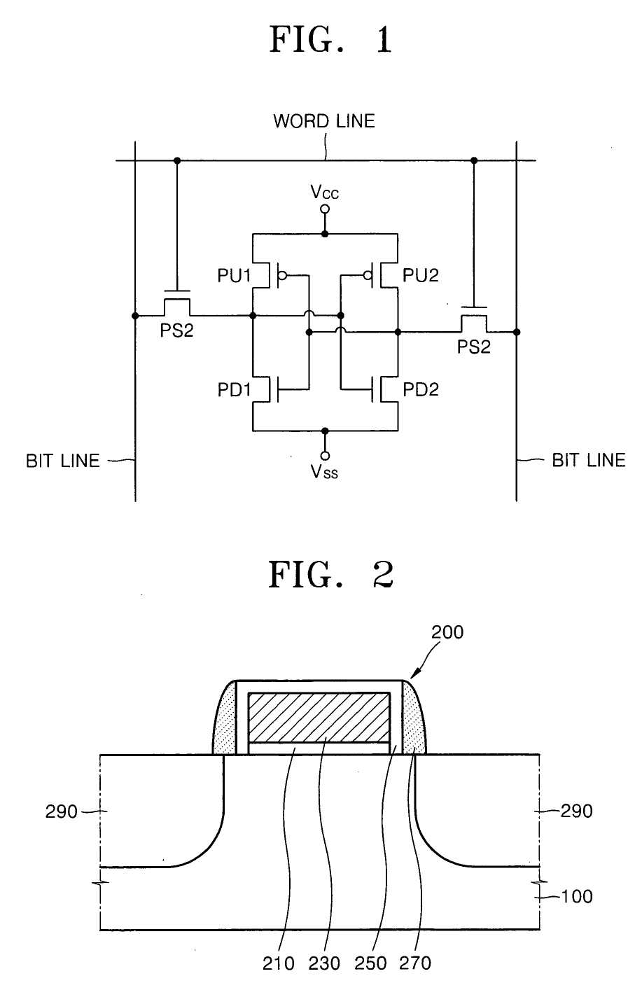

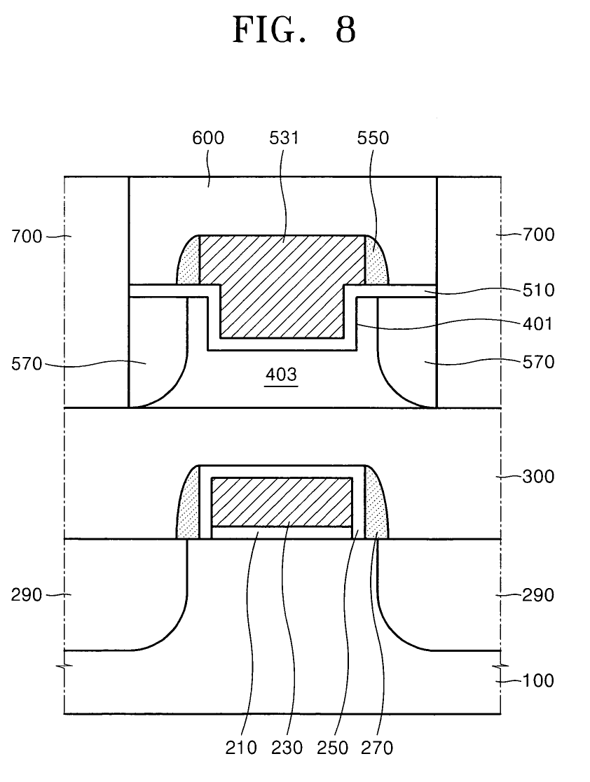

FIGS. 2 through 8 are cross sectional views illustrating a transistor and a methbd of manufacturing the transistor in accordance with an embodiment of the present invention.

Referring to FIG. 2, a first transistor 200 is formed on a semiconductor substrate 100. In more detail, a first gate dielectric layer 210 is formed a silicon semiconductor substrate 100 or a first semiconductor layer of an SOI substrate such as a silicon layer. A channel ion implantation can be performed in advance in order to form a channel. The first gate dielectric layer 210 can be formed, for example. by using a silicon oxide layer or a dielectric layer.

Afterwards, a conductive layer for a first gate, e.g., a conductive polysilicon layer, is formed and patterned into a predetermined configuration to thereby form a first gate 230. The conductive layer can include a metal layer, a doped silicon layer, an undoped silicon layer, or the like. When the first gate 230 includes a predetermined silicon layer, the predetermined silicon layer can be doped with N-typed impurities or P-typed impurities for forming an NMOS transistor or a PMOS transistor.

Thereafter, a first insulating layer 250 is formed to encompass the first gate 230 and then, a first spacer 270 is formed on sidewalls of the first gate 230. The first spacer 270 may be selected from the group consisting of a silicon oxide layer, a silicon oxy-nitride layer, a silicon nitride layer, or a combination thereof. Subsequently, impurity ions are implanted into a predetermined portion of the semiconductor substrate 100 by utilizing the first gate 230 and the first spacer 270 as a mask. At this time, a halo implantation can be further carried out before forming the first spacer 270.

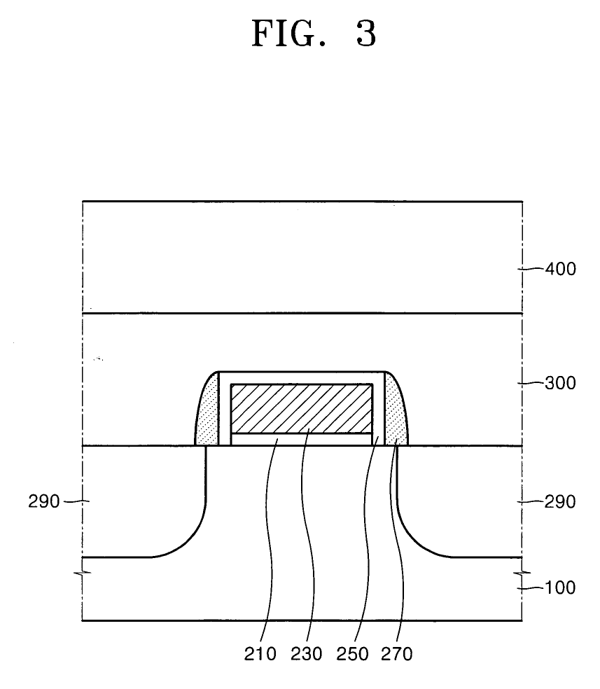

Referring to FIG. 3, an interlayer dielectric (ILD) 300 layer is formed to encompass the first transistor 200, wherein the ILD 300 comprises, for example, a silicon oxide layer.

Thereafter, a second semiconductor layer 400 is formed on the ILD 300, wherein the second semiconductor layer 400, comprises, for example, a silicon layer. Since a channel of the second transistor can be formed in the second semiconductor layer 400, the second semiconductor layer 400 is preferably a single crystal silicon layer.

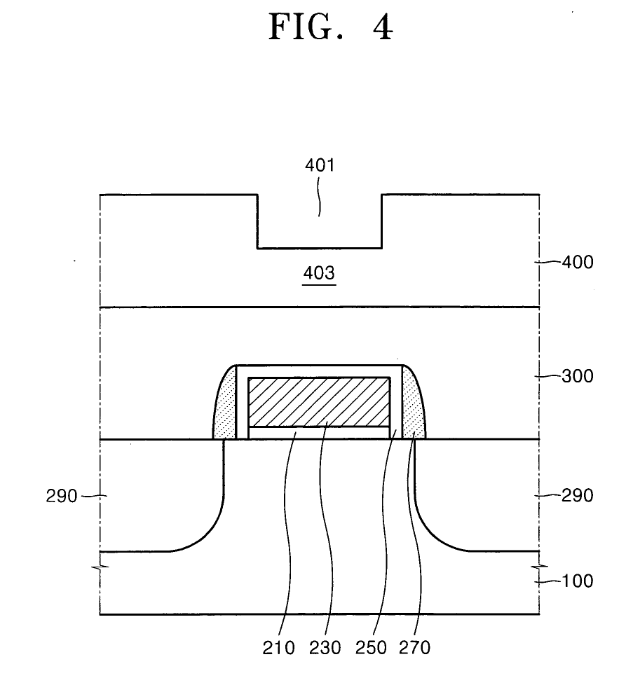

Referring to FIG. 4, the second semiconductor layer 400 is recessed to form a recess groove 401. For instance, after an etching mask (not shown) is formed on a predetermined portion of the second semiconductor layer 400, a portion exposed by the etching mask is selectively etched. An etching angle during the etching for forming the recess groove can be, for example, in a range of about 30-90°. A predetermined region 403 under the recess groove 401 can be used for the channel of the second transistor.

Therefore, the region 403 has a predetermined thickness corresponding to that of a thin silicon body layer in a prior art transistor having a floating thin film within the SOI substrate. Also, it is assumed that the body of the second semiconductor layer 400, except region 403, is thicker than the thin silicon body layer of the conventional transistor.

Accordingly, in order to form the thin channel region 403 in the thick second semiconductor layer 400, it is necessary to perform a recess operation. Thus, since the channel body may have a thickness, for example, in the range of about 200 nm to about 400 nm in the conventional transistor, the second semiconductor layer 400 is etched to form the recess groove 401 in a range of about 1 nm to about 200 nm in depth in the channel region 403. Therefore, the channel region 403 is formed to be relatively thin as compared to other regions of the second semiconductor layer 400.

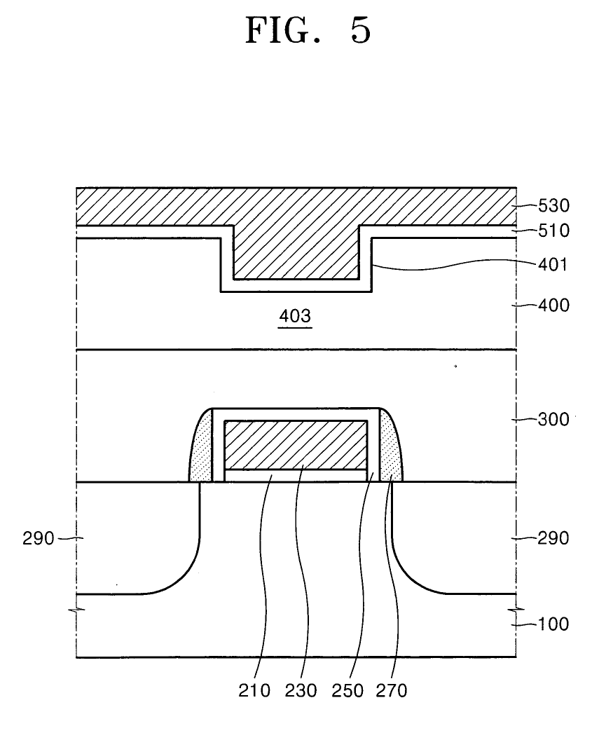

Referring to FIG. 5, a second gate dielectric layer 510 is formed on the second semiconductor layer 400 in which the recess groove 401 is formed. Herein, the second gate dielectric layer 510 is conformally formed along a profile of the recess groove 401. Before the second gate dielectric layer 510 is formed, impurity ions can optionally be implanted into the channel region 403. Such an ion implantation may be carried out after forming the recess groove 401 or, optionally, after forming the second semiconductor layer 400.

Afterwards, a second gate layer 530 is formed on the second gate dielectric layer 510 to fill up the recess groove 401, wherein the second gate layer 530 comprises, for example, a conductive polysilicon layer. In addition, the second gate layer 530 can optionally comprise a metal layer, a doped silicon layer, an undoped silicon layer, or the like. At this time, when the second gate layer 530 is a predetermined silicon layer, the predetermined silicon layer can be doped with N-typed impurities or P-typed impurities for forming an NMOS transistor or a PMOS transistor.

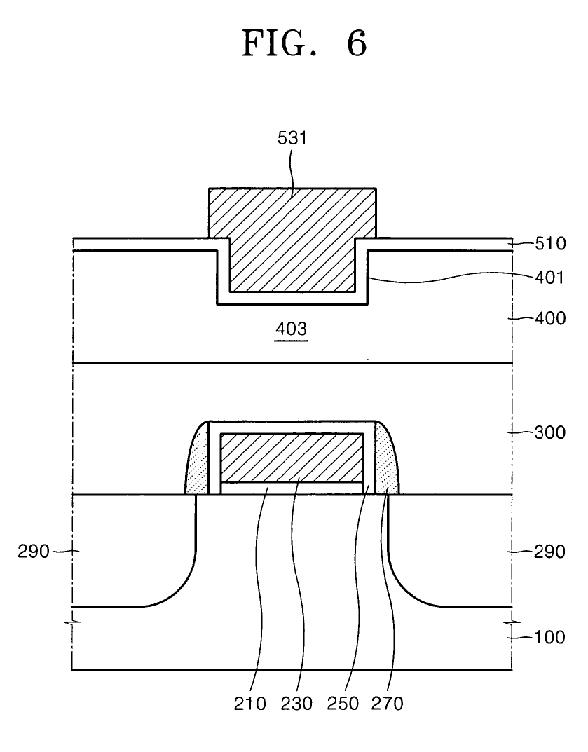

Referring to FIG. 6, the second gate layer 530 is patterned into a preset geometry using a gate etching mask (not shown) through a selective etching, whereby a second gate 531 is formed.

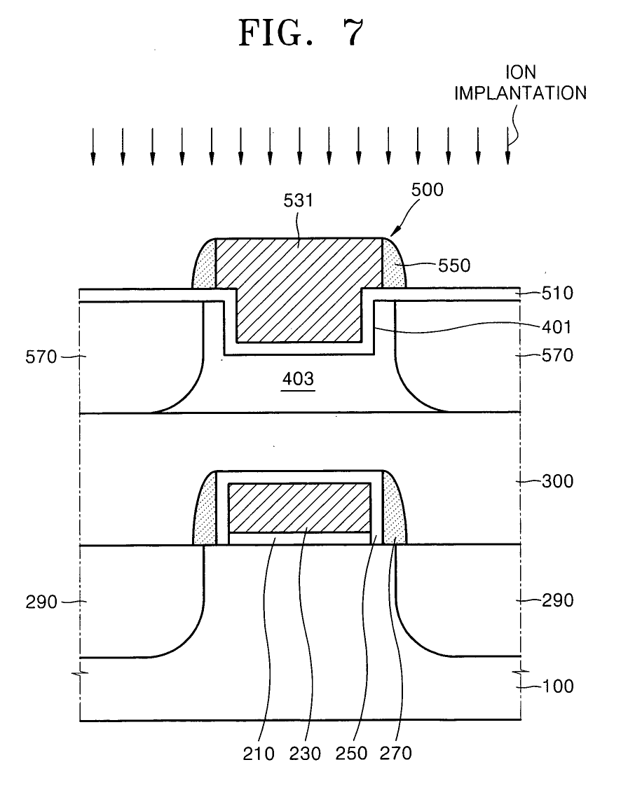

Referring to FIG. 7, a second spacer 550 is formed on sidewalls of the second gate 531, wherein the second spacer 550 may be formed of a silicon oxide layer, a silicon oxy-nitride layer, a silicon nitride layer or a combination thereof. Afterwards, impurity ions are implanted into the second semiconductor layer 400 using the second gate 531 and the second spacer 531 as a mask to thereby form a second source/drain region 570.

At this time, a bottom surface of the second source/drain region 570 is preferably in contact with the underlying ILD 300. Although FIG. 7 shows a case where the distance of the channel region 403 between the second source/drain regions 570 is made longer by means of the recess groove 401, the extend of the second source/drain region 570 can be varied according to ion implantation conditions and according to a post annealing process for activation.

Meanwhile, though it is not shown in FIG. 7, a second insulating layer encompassing the second gate 531 can optionally be provided before forming the second spacer 550. In addition, a halo implantation can be further performed before forming the second spacer 550 using the second gate 531 as a mask.

Thus, the second transistor 500 is formed on the ILD 300, such that the channel region 403 has a relatively thin thickness and the second source/drain regions 570 have a relatively thick thickness.

Referring to FIG, 8, a connection contact 700 is formed in contact with the second source/drain region 570, for instance, after an insulating layer 600 is formed over the second transistor 500. Herein, the contact 700 may be formed to be in contact with a surface of the second source/drain region 570. However, in order to increase the surface area of contact with the second source/drain region 570, bottom end portions of the contact 700 can be buried in the second source/drain region 570.

For example, when a contact hole is formed in the contact 700, a contact hole which penetrates through the insulating layer can be formed in advance. At this time, the surface of the second source/drain region 570 which is exposed by the contact hole is recessed so that the contact hole extends partially into the second semiconductor layer 400. It is possible to form the contact hole to penetrate through the second semiconductor layer 400 so as to expose the underlying ILD 300. Thereafter, a conductive layer is filled into the contact hole and is patterned to form the contact 700. Accordingly, the contact 700 can be formed to be in contact with the surface of the second semiconductor layer 400, i.e., the second source/drain region 570. In addition, the contact 700 can be formed to penetrate through the second semiconductor layer 400. The contact 700 may be also formed by burying a predetermined portion thereof in the second semiconductor layer 400.

As described above, since the second source/drain region 570 which is in contact with the contact 700 is relatively thicker than the channel region 403 in the second semiconductor layer 400, it is possible to increase the contact surface area between the contact 700 and the second source/drain region 570. For instance, since the contact 700 may be formed in such a manner that the bottom end portion thereof is buried in the second source/drain region 570, an effective contact area that is primarily in contact with the second source/drain region 570, e.g., the side portion of the contact 700 that is buried therein, may be increased.

In this manner, it is possible to increase the effective contact surface area that is a key factor to determine a contact resistance between the contact 700 and the second source/drain region 570, to thereby effectively reduce the contact resistance of the contact 700. Thus, it is possible to increase the on-state current of the resulting device.

Meanwhile, in a case where the second transistor 500 is employed for the SRAM cell shown in FIG. 1, the contact 700 can play a role in electrically connecting the second transistor 500 to the other transistor or to electrically connect the second transistor 500 to a bit line or a word line.

Though the transistor of the present invention is illustrated above as a planar transistor, the present invention may be applied to other transistor configurations, including a transistor in which the gate encompasses the body of the channel region or a transistor in which a side portion of the body of the channel region is exposed and a gate is formed on the exposed side portion.

In accordance with the present invention, the source/drain region of the transistor is formed in the thick portion of the semiconductor layer so that it is possible to increase the effective contact surface area between the contact and the source/drain region. In addition, the portion of the semiconductor layer between the source/drain regions, i.e., the channel region, is made to be thinner than the other portions so that an electric field of the channel region is dispersed to reduce a total electric field. As a result, it is possible to decrease the off-state current of the resulting SRAM cell.

Furthermore, a plurality of transistors are vertically stacked to thereby reduce the SRAM cell area. Therefore, it is possible to implement a highly integrated SRAM device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of manufacturing a transistor of an SRAM device, the method comprising:
forming a lower insulating layer on a substrate;
forming a semiconductor layer on the lower insulating layer;
forming a recess groove by selectively recessing the semiconductor layer;
forming a gate dielectric layer on the semiconductor layer;
forming a gate on the gate dielectric layer, wherein the gate fills the recess groove;
forming a source/drain region in the semiconductor layer, adjacent to both sides of the gate;
forming an upper insulating layer covering the gate; and
forming a contact which penetrates through the upper insulating layer so as to be in contact with the source/drain region.

2. The method of claim 1, further comprising before forming the lower insulating layer:
forming a second gate dielectric layer on the substrate;
forming a second gate on the second gate dielectric; and
forming a second source/drain region in the substrate, adjacent to both sides of the second gate.

3. The method of claim 1, wherein the semiconductor layer comprises a silicon layer.

4. The method of claim 1, further comprising, before forming the recess groove: carrying out a channel ion implantation into the semiconductor layer.

5. The method of claim 1, further comprising before forming the gate dielectric layer: carrying out a channel ion implantation into the semiconductor layer below the recess groove.

6. The method of claim 1, wherein a bottom end portion of the contact is partially buried in the source/drain region of the semiconductor layer.

7. The method of claim 1, wherein the contact is formed to penetrate through the source/drain region of the semiconductor layer.

8. A transistor of an SRAM device, comprising:
a lower insulating layer on a substrate;
a semiconductor layer including a recess groove therein on the lower insulating layer, wherein a portion of the semiconductor layer beneath the recess groove is thinner than other portions thereof;
a gate dielectric layer on the semiconductor layer;
a gate on the gate dielectric layer, wherein the gate fills the recess groove;
a source/drain region in the semiconductor layer, adjacent to side portions of the gate; and
a contact connected to the source/drain region.

9. The transistor of claim 8, further comprising:
a second gate dielectric layer on the substrate below the lower insulating layer;
a second gate on the second gate dielectric layer; and
a second source/drain region in a predetermined portion of the substrate which is adjacent to side portions of the second gate.

10. The transistor of claim 9, wherein a bottom end portion of the contact is partially buried in the source/drain region of the semiconductor layer.

11. The transistor of claim 9, wherein the contact penetrates through the source/drain region of the semiconductor layer.

12. The transistor of claim 8, wherein the semiconductor layer comprises a silicon layer.
